(19) United States
(12) Patent Application Publication
(10) Pub. No.: US 2017/0018975 A1
(43) Pub. Date: Jan. 19, 2017

(54) WIRELESS POWER RECEIVER AND METHOD FOR MANUFACTURING THE SAME

(71) Applicant: SAMSUNG ELECTRO-MECHANICS CO., LTD., Suwon-si (KR)

(72) Inventors: Si Hyung KIM, Suwon-si (KR); Tae Sung KIM, Suwon-si (KR); Chul Gyun PARK, Suwon-si (KR); Sung Uk LEE, Suwon-si (KR); Chang Soo KANG, Suwon-si (KR); Hee Sun HAN, Suwon-si (KR)

(73) Assignee: SAMSUNG ELECTRO-MECHANICS CO., LTD., Suwon-si (KR)

(21) Appl. No.: 15/064,679

(22) Filed: Mar. 9, 2016

(30) Foreign Application Priority Data
Jul. 14, 2015 (KR) 10-2015-0100008

(51) Int. Cl. H02J 50/20; H05K 3/32

(52) U.S. Cl. CPC H02J 50/20; H05K 3/32

(57) ABSTRACT

A wireless power receiver and a method for manufacturing the same is disclosed, The wireless power receiver includes a substrate; an antenna configured to transmit a control signal, a coil configured to receive power, and a control unit configured to generate the control signal for wireless receiving power, to convert a received power, and to output a converted power to a load, wherein the antenna, the coil, and the control unit are mounted on the substrate.

### CROSS-REFERENCE TO RELATED APPLICATION(S)

This application claims the priority and benefit under 35 USC §119(a) of Korean Patent Application No. 10-2015-0100008, filed on Jul. 14, 2015 with the Korean Intellectual Property Office, the entire disclosure of which is incorporated herein by reference for all purposes.

### BACKGROUND

1. Field

The following description relates to a wireless power receiver and a method for manufacturing the same.

2. Description of Related Art

A wireless power receiver may include a receiving circuit unit for receiving power transmitted from a wireless power transmitter and a wireless communications unit for performing control operations between the wireless power receiver and the wireless power transmitter.

The wireless power receiver requires an antenna for performing wireless communications with the wireless power transmitter, and may wirelessly transmit power only when the antenna can be connected externally from the wireless power receiver, even if the receiving circuit unit and the wireless communications unit are implemented as one module.

However, the wireless power receiver requires a separate matching element to connect the antenna, and the separate matching element and an external antenna increase the size of the product. Also, expenses for the additional components are increased.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, there is provided a wireless power receiver capable of significantly reducing a size of a module without the need for a separate matching element by mounting an antenna capable of performing wireless communications with a wireless power transmitter together with electronic components such as a coil, to form one integrated module, and a method for manufacturing the same.

In another general aspect, there is provided, a wireless power receiver including a substrate, an antenna configured to transmit a control signal, a coil configured to receive power, and a control unit configured to generate the control signal for wireless receiving power, to convert a received power, and to output a converted power to a load, wherein the antenna, the coil, and the control unit are mounted on the substrate.

The antenna may include a feeding part extending from the substrate, and a radiator may be connected to the feeding part and the radiator may be configured to radiate a control signal transferred from the feeding part.

The radiator may extend from a side of the feeding part and the radiator may form forming a preset angle with the feeding part.

The feeding part and the radiator may be formed integrally with each other.

The feeding part and the radiator may be formed of a stainless steel (SUS) material.

The wireless power receiver may include a sealing part formed on the substrate and the sealing part may be configured to embed the antenna, the coil, and the control unit.

A portion of the antenna may protrude from the sealing part.

The control unit may be configured to transmit the control signal through the antenna.

The substrate may include a multilayer substrate.

The sealing part may be formed of a non-conductive and chemically stable heavy metal material.

The feeding part may extend perpendicularly from the substrate.

In another general aspect, there is provided a method for manufacturing a wireless power receiver, the method including mounting a coil and a control unit on a substrate, mounting an antenna on the substrate, and forming a sealing part embedding the antenna, the coil, and the control unit on the substrate.

The antenna may include a feeding part configured to receive a control signal from the controlling unit, the feeding part connected to the substrate and a radiator extended from the feeding part, and the feeding part and the radiator may be formed integrally with each other.

The radiator may be formed of a stainless steel (SUS) material.

In another general aspect, there is provided a method for manufacturing a wireless power receiver, the method including mounting a coil and a control unit on a substrate, mounting a feeding part of an antenna on the substrate, forming a sealing part to embed the feeding part, the coil, and the control unit on the substrate, radiating a laser to a region on a surface of the sealing part, and forming a radiator of the antenna by metallizing the radiated region.

A length of the feeding part may be longer than a height of the coil and a height of the control unit.

The forming of the radiator may include performing copper plating on the radiated region, and performing nickel plating on the radiated region.

A height of the sealing part may be larger than a length of the feeding part.

A depth of the radiated region may be shallower than a height of the radiator.

Other features and aspects will be apparent from the following detailed description, the drawings, and the claims.

### BRIEF DESCRIPTION OF DRAWINGS

FIG. 1 is a diagram illustrating an example of a wireless power receiver.

FIG. 2 is a diagram illustrating an example of cross-sectional view taken along line A-A′ of the wireless power receiver illustrated in FIG. 1.

FIG. 3 is a diagram illustrating an example of a method for manufacturing a wireless power receiver.

FIGS. 4 through 6 are diagrams illustrating examples of cross-sectional views illustrating the method for manufacturing a wireless power receiver illustrated in FIG. 3.

FIG. 7 is a diagram illustrating an example of a method for manufacturing a wireless power receiver.

FIGS. 8 through 11 are diagrams illustrating examples of cross-sectional views illustrating the method for manufacturing a wireless power receiver illustrated in FIG. 7.

FIG. 12 is a diagram illustrating an example of a method of forming a radiator of FIG. 7.

FIG. 13 is a diagram illustrating an example of a wireless power receiver.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the example embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular embodiments only and is not intended to be limiting of the present inventive concept. As used herein, the singular forms “a,” “an,” and “the” are intended to include the plural forms as well, unless the context clearly indicates otherwise.

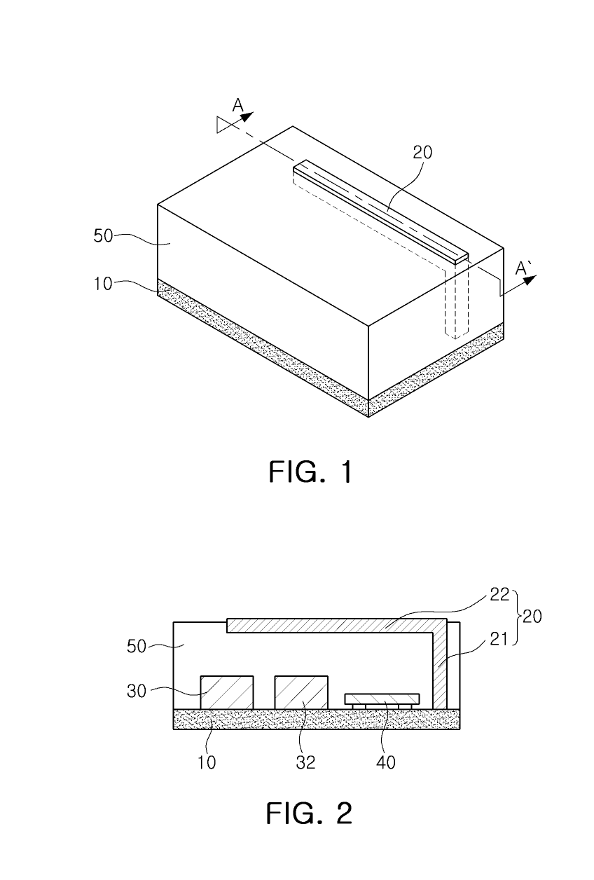

FIG. 1 is a diagram illustrating an example of a wireless power receiver and FIG. 2 is a diagram illustrating an example of cross-sectional view taken along line A-A′ of the wireless power receiver illustrated in FIG. 1.

Referring to FIGS. 1 and 2, a wireless power receiver may include a substrate 10, an antenna 20, a coil 30, and a controlling unit 40. According to an example, the wireless power receiver may further include a sealing part 50. According to an example, the wireless power receiver may further include an electronic parts 32, such as for example, an inductor, and a multi layer ceramic condencer (MLCC).

The substrate 10 may be a printed circuit board (PCB). However, the substrate is not limited to being a PCB, and various kinds of substrates, such as, for example, a ceramic substrate, a glass substrate, a silicon substrate, and a flexible substrate, which are known in the art may be used.

An upper surface of the substrate 10 may be provided with mounting electrodes (not illustrated) for mounting elements, such as, for example, coil 30, antenna 20, and electronic parts 32. In another example, the upper surface of the substrate 10 may be provided with circuit patterns (not illustrated) for electrically connecting the mounting electrodes to each other.

The upper surface of the substrate 10 may also be mounted with the controlling unit 40, which may be electrically connected to the substrate 10 by flip-chip bonding. However, the present disclosure is not limited thereto, and other arrangements for connecting the elements are considered to be well within the scope of the present disclosure. For example, the controlling unit 40 may be electrically connected to the substrate 10 by a bonding wire.

In another example, the substrate 10 may be a multilayer substrate including a plurality of layers, and a wiring pattern (not illustrated) for forming an electrical connection or conductive vias (not illustrated) may be formed between the respective layers.

The antenna 20 may be mounted on the upper surface of the substrate 10 and may radiate a control signal, which is input from the controlling unit 40. In an example, the antenna 20 may radiate the control signal to a wireless power transmitter. In an example, the control signal may be a signal requesting power transmission to the wireless power transmitter. According to an example, the antenna 20 may perform wireless communications with the wireless power transmitter in a frequency band of 2.4 GHz. Power transmitter in other frequency bands are considered to be well within the scope of the present disclosure.

According to an example, the antenna 20 may include a feeding part 21 and a radiator 22.

The feeding part 21 may have one end mounted on the substrate 10 and may be extended in a direction perpendicular to the substrate 10.

The radiator 22 may be connected to the other end of the feeding part 21 and may radiate a control signal transferred from the feeding part 21. Here, the radiator 22 may be extended from one side of the feeding part 21 at a preset angle, for example, 90°.

According to an example, the feeding part 21 and the radiator 22 may be formed integrally with each other. According to an example the feeding part 21 and the radiator 22 may be formed of a stainless steel (SUS) material.

The coil 30 may receive power from the wireless power transmitter (not illustrated). Here, the power received from the wireless power transmitter may be alternating current (AC) power, and the power may be converted into direct current (DC) power by the controlling unit 40 so as to be output to a load (not illustrated).

The controlling unit 40 may generate a control signal for wirelessly receiving power and may transmit the control signal to the wireless power transmitter through the antenna 20. Further, the controlling unit 40 may convert the power received by the coil 30 in response to the control signal and may output the converted power to the load.

According to an example, the controlling unit 40 may include a one or more processors and a memory, and the controlling unit 40 may be an integrated circuit in which the one or more processors and the memory are integrated in at least one chip. In an example, the controlling unit 40 may be electrically connected to the substrate 10 by flip-chip bonding. However, the present disclosure is not limited thereto, and the controlling unit 40 and the substrate 10 may be connected by various manners.

The sealing part 50 may be provided to safely protect electronic components, such as, for example, the antenna 20, the coil 30, the electronic parts 32, and the controlling unit 40, mounted on the substrate 10, from external impact.

The sealing part 50 may be formed to enclose the entire upper surface of the substrate 10 to receive the electronic components mounted on the substrate 10, and may seal the electronic components 20, 30, 32, and 40 on the substrate 10.

In the case of the antenna 20, a portion of the radiator 22 may protrude from the sealing part 50 in order to smoothly communicate with the wireless power transmitter.

The sealing part 50 may be formed by a molding method. In an example, an epoxy mold compound (EMC) may be used as a material of the sealing part 50. According to an example, the sealing part 50 may be formed of a material including a non-conductive and chemically stable heavy metal complex. Other methods, such as, for example, printing method, a spin coating method, a jetting method, may be used for forming the sealing part 50 without departing from the spirit and scope of the illustrative examples described.

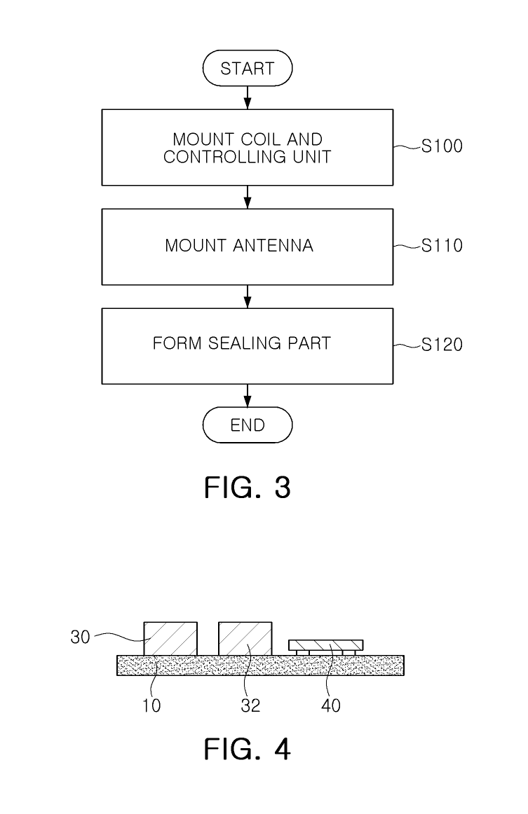

FIG. 3 is a diagram illustrating an example of a method for manufacturing a wireless power receiver, and FIGS. 4 through 6 are diagrams illustrating examples of cross-sectional views illustrating the method for manufacturing a wireless power receiver illustrated in FIG. 3. The operations in FIGS. 3-6 may be performed in the sequence and manner as shown, although the order of some operations may be changed or some of the operations omitted without departing from the spirit and scope of the illustrative examples described. Many of the operations shown in FIGS. 3-6 may be performed in parallel or concurrently. The above description of FIGS. 1-2, is also applicable to FIGS. 3-6, and is incorporated herein by reference. Thus, the above description may not be repeated here.

Referring to FIG. 3, in S100, as shown in FIG. 4, the electronic components such as the coil 30 and the controlling unit 40 may be mounted on the substrate 10.

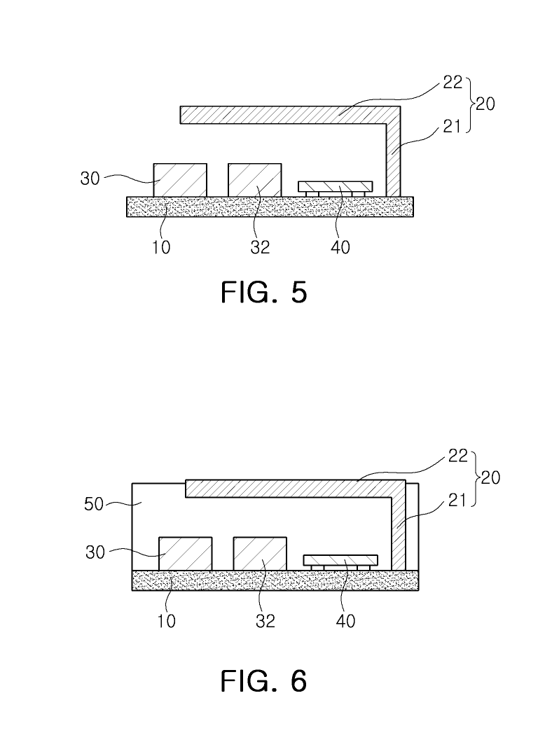

In S110, as shown in FIG. 5, the antenna 20 may be mounted on the substrate 10. The antenna 20 may include the feeding part 21 and the radiator 22. In an example, the feeding part 21 and the radiator 22 may be formed integrally with each other. Further, the feeding part 21 and the radiator 22 may be formed of a stainless steel (SUS) material.

In S120, as shown in FIG. 6, the sealing part 50 embedding the coil 30, the controlling unit 40, and the antenna 20 mounted on the substrate 10 may be formed. According to an example, a portion of the radiator 22 of the antenna 20 may protrude from the sealing part 50 to increase a radiation gain of the antenna.

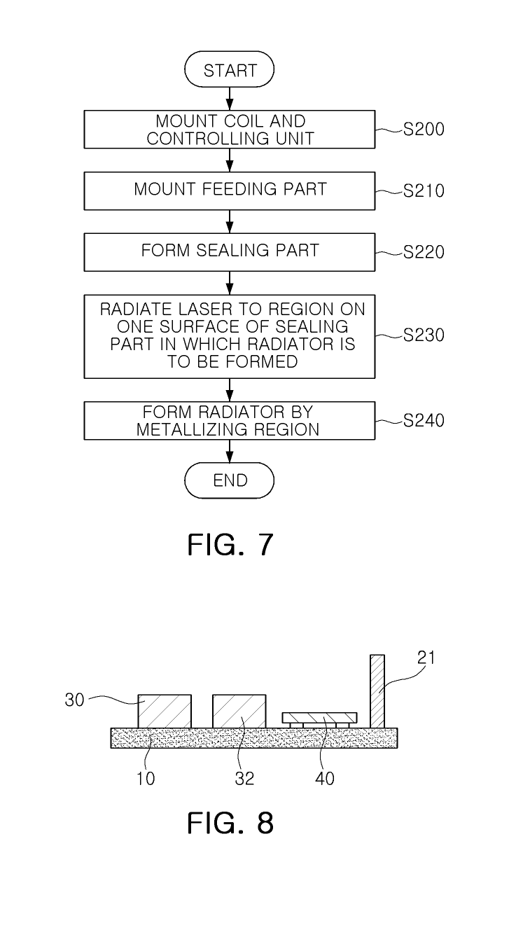

FIG. 7 is a diagram illustrating an example of a method for manufacturing a wireless power receiver. FIGS. 8 through 11 are diagram illustrating examples of cross-sectional views illustrating the method for manufacturing a wireless power receiver illustrated in FIG. 7. The operations in FIGS. 7-11 may be performed in the sequence and manner as shown, although the order of some operations may be changed or some of the operations omitted without departing from the spirit and scope of the illustrative examples described. Many of the operations shown in FIGS. 7-11 may be performed in parallel or concurrently. The above description of FIGS. 1-6, is also applicable to FIGS. 7-11, and is incorporated herein by reference. Thus, the above description may not be repeated here.

In S200, as shown in FIG. 8, the electronic components such as, for example, the coil 30, the electronic parts 32, the controlling unit 40, and the feeding part 21 of the antenna 20 may be mounted on the substrate 10. In an example, a length of the feeding part 21 may be longer than heights of the electronic components such as the coil 30, the electronic parts 32, and the controlling unit 40 mounted on the substrate 10. Unlike the example illustrated in the drawing, S200 and S210 may be performed concurrently or sequentially. That is, the operation (S210) is not necessarily required to be performed after the operation (S200) is performed.

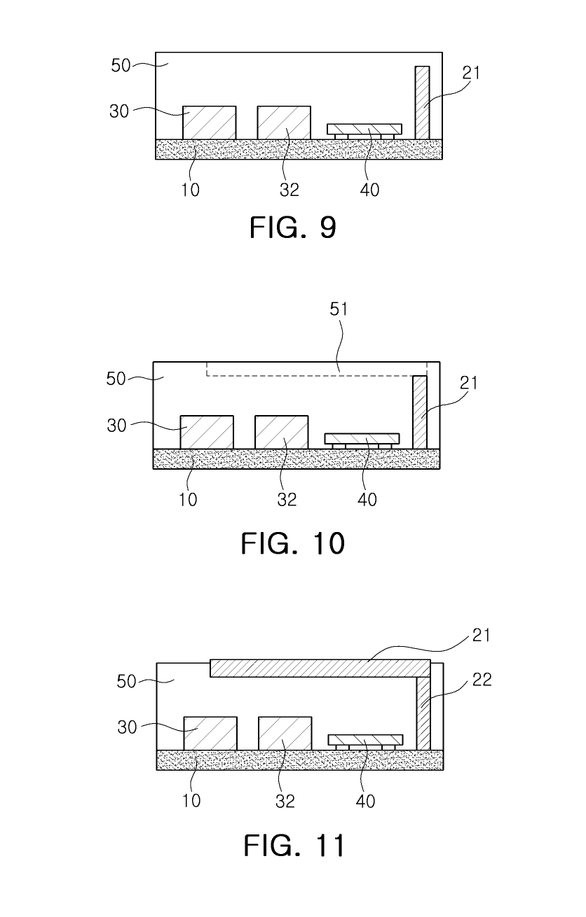

In S220, as shown in FIG. 9, the sealing part 50 embedding the coil 30, the electronic parts 32, the controlling unit 40, and the feeding part 21 mounted on the substrate 10 may be formed. The sealing part 50 may be formed of a material including a polymer material containing a heavy metal complex. An embedding height of the sealing part 50 may be higher than the length of the feeding part 21, and the height may be determined by taking account of a region for forming the radiator 22.

In S230, as shown in FIG. 10, a laser, such as, for example, an ultraviolet (UV) laser, an excimer laser may be radiated to a region 51 on one surface of the sealing part 50 in which the radiator 22 is to be formed. Since the region 51 etched by the laser is the region in which the radiator 22 is to be formed, a portion of the feeding part 21 may be exposed in the region 51.

A depth of the region 51 formed by the laser may be formed by taking account of the height of the radiator 22. According to an example, at least a portion of the radiator 22 may protrude from the sealing part 50 in order to have a predetermined antenna gain. Thus, the depth of the region 51 may be formed to be shallower than the height of the radiator 22 to be formed in the region 51.

In S240, as shown in FIG. 11, the radiator 22 may be formed by metallizing the region 51 of the sealing part 50. Thus, the radiator 22 may be formed on a surface of the sealing part 50 of the region 51 to which the laser is radiated, and may be formed in a shape of the region 51 to which the laser is radiated.

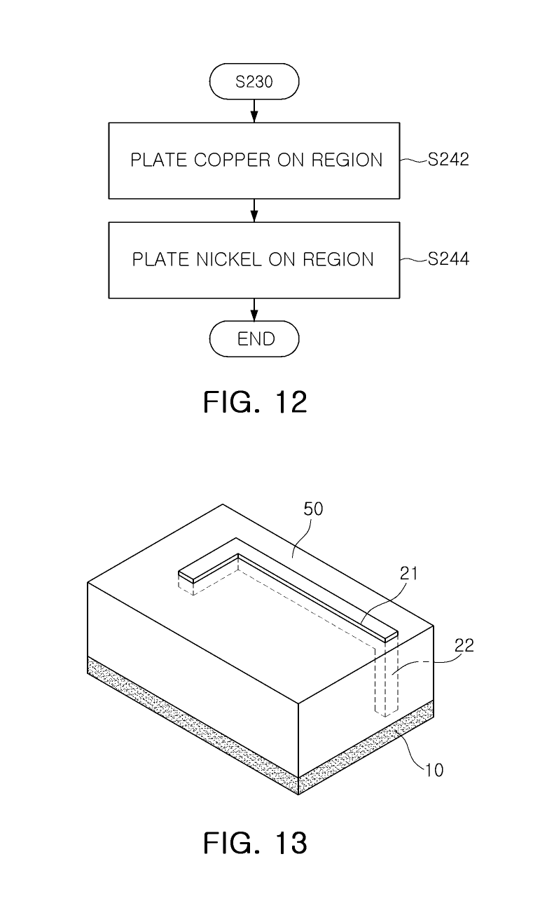

FIG. 12 is a diagram illustrating an example of a method of forming a radiator of FIG. 7. The operations in FIG. 12 may be performed in the sequence and manner as shown, although the order of some operations may be changed or some of the operations omitted without departing from the spirit and scope of the illustrative examples described. Many of the operations shown in FIG. 12 may be performed in parallel or concurrently. The above description of FIG. 1-11, is also applicable to FIG. 12, and is incorporated herein by reference. Thus, the above description may not be repeated here.

Referring to FIG. 12, the operation of forming the radiator according to an example may first include an operation (S242) of performing copper (Cu) plating on the region 51 of the sealing part 50 to which the laser is radiated, in S242, and an operation of performing nickel (Ni) plating on the region 51 in S244.

FIG. 13 is a diagram illustrating an example of a wireless power receiver.

Referring to FIG. 13, in the wireless power receiver according to another example the radiator 22 may be formed in a ‘’ shape, unlike the example illustrated in FIG. 1. However, the shape of the radiator 22 is not limited thereto, and the radiator 22 may be formed in various shapes such as, for example, a ‘⊂’ shape, a ‘W’ shape, as desired.

In order to manufacture the wireless power receiver including the radiator 22 of the above-mentioned shape, the wireless power receiver having a radiation pattern of a desired shape may be manufactured by etching a region of a shape necessary for the sealing part 50 into a necessary shape using the laser in the operation S230, as illustrated in FIGS. 7 and 10. Operation S230 describes radiating the laser to the region 51 on one surface of the sealing part 50 in which the radiator 22 is to be formed and metallizing the region in operation S240.

According to the examples described above , the size of the module may be significantly reduced without the need for a separate matching element by mounting the antenna capable of performing wireless communications with the wireless power transmitter together with the electronic components such as the coil, and the like, to form one integrated module.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A wireless power receiver comprising:
a substrate;
an antenna configured to transmit a control signal;
a coil configured to receive power; and
a control unit configured to generate the control signal for wireless receiving power, to convert a received power, and to output a converted power to a load, wherein the antenna, the coil, and the control unit are mounted on the substrate.

2. The wireless power receiver of claim 1, wherein the antenna comprises:
a feeding part extending from the substrate; and
a radiator connected to the feeding part and the radiator configured to radiate a control signal transferred from the feeding part.

3. The wireless power receiver of claim 2, wherein the radiator is extends from a side of the feeding part and the radiator forming a preset angle with the feeding part.

4. The wireless power receiver of claim 2, wherein the feeding part and the radiator are formed integrally with each other.

5. The wireless power receiver of claim 2, wherein the feeding part and the radiator are formed of a stainless steel (SUS) material.

6. The wireless power receiver of claim 1, further comprising a sealing part formed on the substrate and the sealing part configured to embed the antenna, the coil, and the control unit.

7. The wireless power receiver of claim 6, wherein a portion of the antenna protrudes from the sealing part.

8. The wireless power receiver of claim 1, wherein the control unit is further configured to transmit the control signal through the antenna.

9. The wireless power receiver of claim 1, wherein the substrate comprises a multilayer substrate.

10. The wireless power receiver of claim 6, wherein the sealing part is formed of a non-conductive and chemically stable heavy metal material.

11. The wireless power receiver of claim 2, wherein the feeding part extends perpendicularly from the substrate.

12. A method for manufacturing a wireless power receiver, the method comprising:
mounting a coil and a control unit on a substrate;
mounting an antenna on the substrate; and
forming a sealing part embedding the antenna, the coil, and the control unit on the substrate.

13. The method of claim 12, wherein the antenna comprises a feeding part configured to receive a control signal from the controlling unit, the feeding part connected to the substrate and a radiator extended from the feeding part, and the feeding part and the radiator being formed integrally with each other.

14. The method of claim 13, wherein the feeding part and the radiator are formed of a stainless steel (SUS) material.

15. A method for manufacturing a wireless power receiver, the method comprising:
mounting a coil and a control unit on a substrate;
mounting a feeding part of an antenna on the substrate;
forming a sealing part to embed the feeding part, the coil, and the control unit on the substrate;
radiating a laser to a region on a surface of the sealing part; and
forming a radiator of the antenna by metallizing the radiated region.

16. The method of claim 15, wherein a length of the feeding part is longer than a height of the coil and a height of the control unit.

17. The method of claim 15, wherein the forming of the radiator comprises:
performing copper plating on the radiated region; and
performing nickel plating on the radiated region.

18. The method of claim 15, wherein a height of the sealing part is larger than a length of the feeding part.

19. The method of claim 15, wherein a depth of the radiated region is shallower than a height of the radiator.
